(19) United States
(12) Patent Application Publication
(10) Pub. No.: US 2008/0264682 A1
(43) Pub. Date: Oct. 30, 2008

(54) Substrate and negative imaging method for providing transparent conducting patterns

(76) Inventors: John Catron, Smyrna, DE (US); Feng Gao, Hockessin, DE (US); Lynda Kaye Johnson, Wilmington, DE (US); Jeffrey Scott Meth, Landenberg, PA (US); Stephen G. Zane, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 11/789,222

(22) Filed: Apr. 24, 2007

(51) Int. Cl. H05K 1/09

(52) U.S. Cl. 174/257; 250/492.1

(57) ABSTRACT

Provided are processes for making a transparent conducting pattern. The invention is also directed to electronic devices containing such transparent conducting patterns. Further provided is a substrate comprising a base film and a transparent conducting layer disposed on the base film; wherein the substrate has an OD of about 0.1 to 0.6 at 830 nm, and the transparent conducting layer comprises polyethylene dioxythiophene and has an OD of less than 0.1 in the range of 400 to 700 nm.

### FIELD OF INVENTION

The invention relates to substrates and processes for providing transparent conducting patterns for electrical applications.

### BACKGROUND

Transparent electrically-conductive layers of metal oxides such as indium tin oxide (ITO), antimony doped tin oxide, and cadmium stannate (cadmium tin oxide) are commonly used in the manufacture of electrooptical display devices such as liquid crystal display devices (LCDs), electroluminescent display devices, photocells, solid-state image sensors, electrochromic windows and the like.

Devices such as flat panel displays typically contain a substrate provided with an indium tin oxide (ITO) layer as a transparent electrode. The coating of ITO is carried out by vacuum sputtering methods which involve high substrate temperature conditions up to 250° C., and therefore, glass substrates are generally used. The high cost of the fabrication methods and the low flexibility of such electrodes, due to the brittleness of the inorganic ITO layer as well as the glass substrate, limit the range of potential applications. As a result, there is a growing interest in making all-organic devices, comprising plastic resins as a flexible substrate and organic electroconductive polymer layers as an electrode. Such plastic electronics allow low cost devices with new properties. Flexible plastic substrates can be provided with an electroconductive polymer layer by roller coating methods and the resulting organic electrodes enable the “roll to roll” fabrication of electronic devices which are more flexible, lower cost, and lower weight.

Electronically conductive polymers have recently received attention from various industries because of their electronic conductivity. Although many of these polymers are highly colored and are less suited for transparent conductive layer applications, some of these electronically conductive polymers, such as substituted or unsubstituted pyrrole-containing polymers, substituted or unsubstituted thiophene-containing polymers, and substituted or unsubstituted aniline-containing polymers are transparent and not prohibitively colored, at least when coated in thin layers at moderate coverage. Because of their electronic conductivity these polymers can provide excellent process-surviving, humidity independent antistatic characteristics when coated on plastic substrates used for photographic imaging applications.

Although there are known methods to form and pattern electronically conductive polymers, there are some applications where it may be difficult or impractical to involve any wet processing or cumbersome patterning steps. For example, wet processing during coating and/or patterning may adversely affect integrity, interfacial characteristics, and/or electrical or optical properties of the previously deposited layers. Additionally, the device manufacturer may not have coating facilities to handle a large quantity of liquid. It is conceivable that many potentially advantageous device constructions, designs, layouts, and materials are impractical because of the limitations of conventional wet coating and patterning. There is a need for new methods of forming these devices with a reduced number of processing steps, particularly wet processing steps. In at least some instances, this may allow for the construction of devices with more reliability and more complexity.

Use of thermal transfer elements and thermal transfer methods for forming multicomponent devices have been proposed previously. For example, Wolk et al, in U.S. Pat. No. 6,114,088 and related patents, disclose thermal transfer elements and methods, for multilayer devices. However, such elements are non-transparent, often including a pigmented or metallized light-to-heat conversion layer, colored transfer layer, and the like.

US 2006/0088698 A1, Majumdar, et al, discloses a donor laminate for transfer of a conductive layer comprising at least one electronically conductive polymer onto a receiver, wherein the receiver is a component of a device. Particular electronically conductive layers disclosed comprise polyethylene dioxythiophene and although a visual light transmission of greater than 90% was stated for the conductive layer, no examples meeting the 90% visual transmission were disclosed. Thus, there is still a need in the art for a suitable transfer element and a transfer method to form transparent conductive patterns, and incorporating such conductive patterns in electronic and/or optical devices.

### SUMMARY OF THE INVENTION

One aspect of the invention is a process for making a transparent conducting pattern comprising:

(a) providing a substrate comprising: a base film and a transparent conducting layer disposed on the base film wherein the substrate has an OD of about 0.1 to 0.6 at 830 nm, and the transparent conducting layer has an average OD of less than 0.1 in the range of 400 to 700 nm;

(b) contacting the substrate with a receiver, wherein the receiver comprises a base film, to provide an assemblage; and

(c) exposing a portion of the assemblage to an IR light beam to provide an exposed substrate having at least one exposed region, and at least one unexposed region having the transparent conducting pattern; and an exposed receiver; wherein a ratio of the surface electrical resistance of the exposed region and unexposed region is at least 1000:1.

Another aspect of the invention is an electronic device made by the process as disclosed above.

Another aspect of the invention is a substrate comprising: a base film and a transparent conducting layer disposed on the base film; wherein the substrate has an OD of about 0.1 to 0.6 at 830 nm, and the transparent conducting layer comprises polyethylene dioxythiophene and has an OD of less than 0.1 in the range of 400 to 700 nm.

### DETAILED DESCRIPTION

All patents and patent applications cited herein are hereby incorporated by reference. All trademarks herein are designated with capital letters.

Herein the terms “acrylic”, “acrylic resin”, “(meth)acrylic resins”, and “acrylic polymers”, are synonymous unless specifically defined otherwise. These terms refer to the general class of addition polymers-derived from the conventional polymerization of ethylenically unsaturated monomers derived from methacrylic and acrylic acids and alkyl and substituted-alkyl esters thereof. The terms encompass homopolymers and copolymers. The terms encompass specifically the homopolymers and copolymers of methyl(meth)acrylate, ethyl(meth)acrylate, butyl(meth)acrylate, 2-hydroxyethyl(meth)acrylate, (meth)acrylic acid and glycidyl (meth)acrylate. The term copolymer herein encompasses polymers derived from polymerization of two or more monomers, unless specifically defined otherwise. The term (meth)acrylic acid encompasses both methacrylic acid and acrylic acid. The term (meth)acrylate, encompasses methacrylate and acrylate.

The terms “styrene acrylic polymers”, “acrylic styrene” and “styrene acrylic” are synonymous and encompass copolymers of the above described “acrylic resins” with styrene and substituted styrene monomers, for instance alpha-methyl styrene.

One embodiment of the invention is a process for making a transparent conducting pattern comprising: (a) providing a substrate comprising: a base film and a transparent conducting layer disposed on the base film wherein the substrate has an OD of about 0.1 to 0.6, and preferably about 0.1 to 0.3, at 830 nm; and the transparent conducting layer has an average OD of less than 0.1, and preferably less than 0.08, in the range of 400 to 700 nm.

The base film provides support to the other layers of the substrate. The base film comprises a flexible polymer film and is preferably substantially transparent in the visible region. A suitable thickness for the base film is about 25 μm to about 200 μm, although thicker or thinner support layers may be used. The base film may be stretched by standard processes known in the art for producing oriented films; and one or more other layers, such as a light-to-heat conversion (LTHC) layer, defined below, may be coated onto the base film prior to completion of the stretching process. Preferred base films comprise a polymeric material selected from the group consisting of: polyethylene terephthalate (PET), polyethylene naphthalate (PEN), triacetyl cellulose (TAC), TEDLAR ethylene-tetrafluoroethylene copolymers (E.I. du Pont de Nemours and Company, Wilmington, Del.), and polyimide. Generally, PET is especially preferred as a base film. The ethylene-tetrafluoroethylene copolymers are preferred base films in processes wherein the transparent conducting pattern is used in a photovoltaic current collector, or similar electronic devices that may be exposed to moisture and weathering conditions. TAC is preferred for display applications.

The base film can comprise a single layer or multiple layers according to need. The multiplicity of layers may include any number of additional layers such as antistatic layers, tie layers or adhesion promoting layers, abrasion resistant layers, curl control layers, conveyance layers, barrier layers, splice providing layers, optical effect providing layers, such as antireflective and antiglare layers, waterproofing layers, adhesive layers, release layers, magnetic layers, interlayers, imageable layers and the like. For instance, and preferably, the base film can further comprise a thin adhesive layer of dielectric polymer that promotes adhesion of subsequently coated layers including the transparent conducting layer to the base film. The adhesive layer may be a pressure sensitive adhesive layer comprising a low Tg polymer, a heat activated adhesive layer comprising a thermoplastic polymer, or a thermally or radiation curable adhesive layer. Examples of suitable polymers for use in the adhesive layer include styrenic polymers, polyolefins, polycarbonate, polyurethane, polyester; polyvinyl chloride; styrene/acrylonitrile copolymer; poly(caprolactone): vinylacetate copolymers with ethylene and/or vinyl chloride; (meth)acrylate homopolymers (such as butyl-methacrylate) and copolymers; and mixtures thereof; and other polymers well known in the adhesives industry.

The transparent conducting layer can comprise any conducting material having substantial transparency in the visible region. Preferred are organic conductors such as substituted or unsubstituted pyrrole-containing polymers (as mentioned in U.S. Pat. Nos. 5,665,498 and 5,674,654), substituted or unsubstituted thiophene-containing polymers (as mentioned in U.S. Pat. Nos. 5,300,575, 5,312,681, 5,354,613, 5,370,981, 5,372,924, 5,391,472, 5,403,467, 5,443,944, 5,575,898, 4,987,042, and 4,731,408) and substituted or unsubstituted aniline-containing polymers (as mentioned in U.S. Pat. Nos. 5,716,550, 5,093,439, and 4,070,189). However, particularly suitable are those, which comprise an electronically conductive polymer in its cationic form and a polyanion, since such a combination can be formulated in aqueous medium and hence is environmentally desirable. Examples of such polymers are disclosed in U.S. Pat. Nos. 5,665,498 and 5,674,654 for pyrrole-containing polymers and U.S. Pat. No. 5,300,575 for thiophene-containing polymers. Among these, the thiophene-containing polymers are most preferred because of their light and heat stability, dispersion stability and ease of storage and handling.

Preferably the transparent conducting layer comprises polyethylene dioxythiophene; and more preferably, in order to meet the OD requirements of less than 0.1 in the range of 400 to 700 nm, the transparent conducting layer generally has a thickness of less than 400 nm. However the transparent conducting layer may be thicker than 400 nm, if so desired, and still meet the OD requirements. For instance, a transparent conducting layer can further comprise a film-forming binder, further discussed below, that effectively reduces the OD of the transparent conducting layer on a unit thickness basis.

A preferred embodiment, useful for practicing the processes of the invention, is a substrate comprising: a base film and a transparent conducting layer disposed on the base film; wherein the donor has an OD of about 0.1 to 0.6 at 830 nm, and the transparent conducting layer comprises polyethylene dioxythiophene and has an OD of less than 0.1 in the range of 400 to 700 nm. All other preferences described herein for the substrate useful in the process of the invention also apply to the aforementioned substrate.

Preparation of the Aforementioned Thiophene Based Polymers is disclosed in a publication titled “Poly(3,4-ethylenedioxythiophene) and its derivatives: past, present and future” by L. B. Groenendaal, F. Jonas, D. Freitag, H. Pielartzik and J. R. Reynolds in Advanced Materials, (2000), 12, No. 7, pp. 481-494, and references therein. In a preferred embodiment, the transparent conducting layer is prepared by applying a mixture comprising:

(i) a polythiophene according to Formula (I)

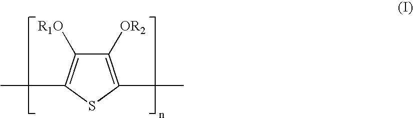

in a cationic form, wherein each of R₁ and R₂ independently represents hydrogen or a C1-4 alkyl group or together represent an optionally substituted C1-4 alkylene group or a cycloalkylene group, preferably an ethylene group, an optionally alkyl-substituted methylene group, an optionally C1-12 alkyl- or phenyl-substituted 1,2-ethylene group, a 1,3-propylene group or a 1,2-cyclohexylene group; and n is 3 to 1000; and
(ii) a polyanion compound.

It is preferred that the polythiophene and polyanion combination is soluble or dispersible in organic solvents or water or mixtures thereof. For environmental reasons, aqueous systems are preferred. Polyanions used with these electronically conductive polymers include the anions of polymeric carboxylic acids such as polyacrylic acids, poly(methacrylic acid), and poly(maleic acid), and polymeric sulfonic acids such as polystyrenesulfonic acids and polyvinylsulfonic acids, the polymeric sulfonic acids being preferred for use in this invention because of its stability and availability in large scale. These polycarboxylic and polysulfonic acids may also be copolymers formed from vinylcarboxylic and vinylsulfonic acid monomers copolymerized with other polymerizable monomers such as the esters of acrylic acid and styrene. The molecular weight of the polyacids providing the polyanions preferably is 1,000 to 2,000,000 and more preferably 2,000 to 500,000. The polyacids or their alkali salts are commonly available, for example as polystyrenesulfonic acids and polyacrylic acids, or they may be produced using known methods. Instead of the free acids required for the formation of the electrically conducting polymers and polyanions, mixtures of alkali salts of polyacids and appropriate amounts of monoacids may also be used. The polythiophene to polyanion weight ratio can widely vary between 1:99 to 99:1, however, optimum properties such as high electrical conductivity and dispersion stability and coatability are obtained between 85:15 and 15:85, and more preferably between 50:50 and 15:85. The most preferred electronically conductive polymers include poly(3,4-ethylene dioxythiophene styrene sulfonate) which comprises poly(3,4-ethylene dioxythiophene) in a cationic form and polystyrenesulfonic acid.

The process of the invention requires the substrate to have an OD of about 0.1 to 0.6, preferably about 0.1 to about 0.3, at 830 nm. This OD is useful in absorption of energy from an imaging near-IR laser, or other near-IR light source, in the exposing step; while maintaining a low OD, for instance, less than 0.1 OD in the range of 400-700 nm. The OD requirement of the substrate can be met by any means so long as it does not adversely impact the OD of the transparent conducting layer in the visible region. Preferably the substrate comprises one or more near-IR dye(s) having an absorption maximum in the range of about 600 to about 1200 nm within the substrate. Preferred classes of near-infrared dyes are cyanine compounds selected from the group consisting of: indocyanines, phthalocyanines including polysubstituted phthalocyanines and metal-containing phthalocyanines, and merocyanines.

Sources of suitable near-IR absorbing dyes include H. W. Sands Corporation (Jupiter, Fla., US), American Cyanamid Co. (Wayne, N.J.), Cytec Industries (West Paterson, N.J.), Glendale Protective Technologies, Inc. (Lakeland, Fla.) and Hampford Research Inc. (Stratford, Conn.). Preferred dyes for the substrate are 3H-indolium, 2-[2-[2-chloro-3-[(1,3-dihydro-1,3,3-trimethyl-2H-indol-2-ylidene)ethylidene]-1-cyclopenten-1-yl]ethenyl]-1,3,3-trimethyl-, salt with trifluoromethanesulfonic acid (1:1) having CAS No. [128433-68-1], available from Hampford Research Inc, Stratford, Conn., as TIC-5c; 2-(2-(2-chloro-3-(2-(1,3-dihydro-1,1-dimethyl-3-(4-sulphobutyl)-2H-benz[e]indol-2-ylidene)ethylidene)-1-cyclohexene-1-yl)ethenyl)-1,1-dimethyl-3-(4-sulphobutyl)-1H-benz[e]indolium, inner salt, free acid having CAS No. [162411-28-1], available from H. W. Sands Corp, as SDA 4927; and indolenine dyes SDA 2860 and SDA 4733 from H. W. Sands Corp. SDA 4927 is an especially preferred dye for the substrate. For substrates prepared with water-based formulations, SDA 4927 and SDA 2860 are preferred dyes.

The near-IR dye(s) can be present in a variety of layers within the substrate. In one preferred embodiment, one or more near-IR dye(s) is disposed in the transparent conducting layer. The near-IR dye(s) are present at about 1.0 to 30 wt %, preferably about 3.0 to 25 wt %, and more preferably about 5.0 to 20 wt %, based on a dry weight of the transparent conducting layer. A transparent conducting layer comprising one or more near-IR dye(s) can be made by blending the dye in a solvent, for instance methanol, that is compatible with the material making up the transparent conducting layer. The mixture can then be coated on the base film, or other layers on the base film to provide a thin transparent conducting layer comprising the one or more near-IR dye(s), as disclosed below.

In another preferred embodiment, the substrate further comprises a light-to-heat-conversion (LTHC) layer interposed between the base film and the transparent conducting layer. The LTHC layer is incorporated as a part of the substrate to couple the energy of light radiated from a near-IR light source into the substrate. Typically, the radiation absorber in the LTHC layer (or other layers) absorbs light in the infrared region of the electromagnetic spectrum and converts the absorbed light into heat. In this preferred embodiment the LTHC layer comprises one or more dielectric polymer(s) and the one or more near-IR dye(s) as disclosed above.

In preferred embodiments, the one or more dielectric polymer(s) useful in the LTHC layer is based upon a broad variety of water-soluble or water-dispersible polymeric binders with compositions as disclosed in PCT/US05/38010 and PCT/US05/38009. Preferably, the average particle size of a water-dispersible binder in its aqueous phase is less than 0.1 micron, and more preferably less than 0.05 micron, and preferably having a narrow particle size distribution.

Preferred water-soluble or water-dispersible polymeric binders for LTHC layers useful in the invention are those selected from the group: acrylic resins and hydrophilic polyesters and more preferably sulphonated polyesters as described in the above referenced PCT/US05/38009. Other preferred polymeric binders for LTHC layers are maleic anhydride polymers and copolymers including those comprising functionality provided by treating the maleic anhydride polymers and/or copolymers with alcohols, amines, and alkali metal hydroxides. Specific maleic anhydride based copolymers comprise the structure represented by formula (II)

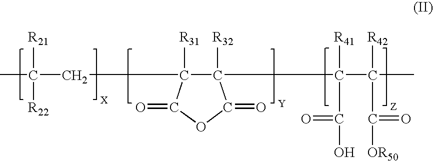

wherein x and z are any positive integer;
wherein y is zero or any positive integer;
R₂₁ and R₂₂ can be the same or different, and individually are hydrogen, alkyl, aryl, aralkyl, cycloalkyl, and halogen, provided that one of R₂₁ and R₂₂ is an aromatic group;
R₃₁, R₃₂, R₄₁ and R₄₂ are the same or different groups, which can be hydrogen or alkyl of one to about five carbon atoms; and
R₅₀ is functional group selected from the group comprising:

a) alkyl, aralkyl, alkyl-substituted aralkyl radicals containing from one to about twenty carbon atoms;

b) oxyalkylated derivatives of alkyl, aralkyl, alkyl-substituted aralkyl radicals containing from about two to about four carbon atoms in each oxyalkylene group, which can be of one to about twenty repeating units;

c) oxyalkylated derivatives of alkyl, aralkyl, alkyl-substituted aralkyl radicals containing from about two to about four carbon atoms in each oxyalkylene group, which can be of one to about six repeating units;

d) at least one unsaturated moiety;

e) at least one heteroatom moiety;

f) alkaline molecules capable of forming salts selected from Li, Na, K and NH₄⁺; and

g) combinations thereof.

A preferred maleic anhydride polymer for LTHC layers comprises a copolymer of formula (II), wherein R₂₁, R₃₁, R₃₂, R₃₃, R₄₁, R₄₂, R₄₃, are individually hydrogen, R₂₂ is phenyl, and R₅₀ is 2-(n-butoxy)ethyl. A specific example of a maleic anhydride copolymer useful in LTHC layers is a styrene maleic anhydride copolymer such as SMA 1440H, a product of Sartomer Corporation, Exton, Pa.

A preferred LTHC layer for the substrate and processes of the invention comprises one or more water-soluble or water-dispersible radiation-absorbing cyanine compound(s) selected from the group consisting of: indocyanines, phthalocyanines including polysubstituted phthalocyanines and metal-containing phthalocyanines, and merocyanines; and one or more water-soluble or water-dispersible polymeric binders selected from the group consisting of: acrylic resins, hydrophilic polyesters, sulphonated polyesters, and maleic anhydride homopolymers and copolymers. A most preferred LTHC layer further comprises one or more release modifiers selected from the group consisting of: quaternary ammonium cationic compounds; phosphate anionic compounds; phosphonate anionic compounds; compounds comprising from one to five ester groups and from two to ten hydroxyl groups; alkoxylated amine compounds; and combinations thereof.

A LTHC layer comprising one or more near-IR dye(s) can be made by blending the one or more near-IR dye(s) in a solvent, for instance methanol, that is compatible with the dielectric polymer(s) making up the LTHC layer. The mixture can then be coated on the base film, or other layers on the base film to provide a thin near-IR absorptive layer comprising the one or more near-IR dye(s). The polymeric or organic LTHC layer is coated to a thickness of 0.05 □m to 20 □m, preferably, 0.05 □m to 10 □m, and, more preferably, 0.1 □m to 5 □m. In these thickness ranges the near-IR dye(s) are present at about 1.0 to 20 wt %, preferably about 1.0 to about 10 wt %, based on a dry weight of the LTHC layer.

In another embodiment, the desired OD of the substrate can be accomplished by disposing the one or more near-IR dye(s) in both the transparent conducting layer and an LTHC layer, using a combination of coating processes as disclosed above.

The transparent conducting layer and other layers disclosed herein including the optional LTHC layer, the conducting transfer layer for the donor (disclosed below), and other optional layers such as adhesive layers, can be formed by any method known in the art. Particularly preferred methods include coating from a suitable coating composition by any well known coating method. For instance rod coating, spin-coating, spraying, gravure coating, hopper coating, curtain coating, roller coating, electrochemical coating, inkjet printing, flexographic printing, and stamping can be used. Coating and spraying are preferred methods for applying the coating compositions.

While the conductive layer can be formed without the addition of a film-forming polymeric binder, a film-forming binder can be employed to improve the physical properties of the layer. In such an embodiment, the layer may comprise from about 1 to 95% of the film-forming polymeric binder. However, the presence of the film forming binder may increase the overall surface electrical resistivity of the layer. The optimum weight percent of the film-forming polymer binder varies depending on the electrical properties of the electronically conductive polymer, the chemical composition of the polymeric binder, and the requirements for the particular circuit application.

Polymeric film-forming binders useful in the transparent conducting layer of this invention can include, but are not limited to, water-soluble or water-dispersible hydrophilic polymers such as gelatin, gelatin derivatives, maleic acid or maleic anhydride copolymers, polystyrene sulfonates, cellulose derivatives (such as carboxymethyl cellulose, hydroxyethyl cellulose, cellulose acetate butyrate, diacetyl cellulose, and triacetyl cellulose), polyethylene oxide, polyvinyl alcohol, and poly-N-vinylpyrrolidone. Other suitable binders include aqueous emulsions of addition-type homopolymers and copolymers prepared from ethylenically unsaturated monomers such as acrylates including acrylic acid, methacrylates including methacrylic acid, acrylamides and methacrylamides, itaconic acid and its half-esters and diesters, styrenes including substituted styrenes, acrylonitrile and methacrylonitrile, vinyl acetates, vinyl ethers, vinyl and vinylidene halides, and olefins and aqueous dispersions of polyurethanes and polyesterionomers.

Other ingredients that may be included in the transparent conducting layer include but are not limited to surfactants, defoamers, coating aids, charge control agents, thickeners, viscosity modifiers, antiblocking agents, crosslinking agents, hardeners, inorganic or polymeric particles, adhesion promoting agents, bite solvents, plasticizers, antioxidants, and other addenda that are well-known in the art. Preferred bite solvents include any of the volatile aromatic compounds disclosed in U.S. Pat. No. 5,709,984, as “conductivity-increasing” aromatic compounds, comprising an aromatic ring substituted with at least one hydroxy group or a hydroxy substituted substituents group. Preferred surfactants suitable for these coatings include nonionic and anionic surfactants.

The transparent conducting layer of the invention should contain about 1 to about 1000 mg/m² dry coating weight of the electronically conductive polymer. Preferably, the transparent conducting layer should contain about 5 to about 500 mg/m² dry coating weight of the electronically conductive polymer. The actual dry coating weight of the conductive polymer applied is determined by the properties of the particular conductive polymer employed and by the requirements of the particular application. These requirements include conductivity, transparency, optical density and cost for the layer.

A key criterion of the transparent conducting layer of the invention involves-two important characteristics: transparency in the range of 400 to 700 nm, also referred to as visual light transmission, and surface electrical resistance (SER). The stringent requirement of high transparency and low SER demanded by modern display devices can be extremely difficult to attain with electronically conductive polymers. Typically, lower SER values are obtained by coating relatively thick layers which undesirably reduces visual light transmission. Additionally, even the same general class of conductive polymers, such as polythiophene containing polymers, may result in different SER and transparency characteristics, based on differences in molecular weight, impurity content, doping level, morphology and the like.

Light transmission is related to optical density by the relationship

OD=10^{(-%T/100)}

where % T is the percentage of light transmitted with respect to a reference, and OD is the optical density. The average transmission is the transmission averaged over the range 400-700 nm. The average optical density is the optical density averaged over the range 400-700 nm.

The SER value of the substrate of the invention and the transparent conducting pattern provided by the invention can vary according to need. For use as an electrode in a display device, the SER is typically less than 10000 ohms/square, preferably less than 5000 ohms/square, and more preferably less than 1000 ohms/square and most preferably less than 500 ohms/square, as per the current invention.

In a preferred embodiment the donor of the invention, useful in the process of the invention, has a peel force greater than 100 grams linear per inch (about 40 g/cm), and preferably greater than about 500 grams per linear inch (about 200 g/cm). This can be readily accomplished using an adhesive layer as disclosed above, disposed between the transparent conducting layer and the base film. One of the significant attributes of the invention is that the exposing step requires only the removal, or partial removal, of the transparent conducting layer in the exposed regions. The unexposed regions remaining on the substrate provide the desired transparent conducting pattern. Thus the peel force of the transparent conducting layer can be designed to be significantly higher than conventional thermal transfer layers. For instance, the donor disclosed in US 2006/0088698 A1, Majumdar, et al, has a preferred peel strength of less than 100 g/inch, (40 g/cm) and more preferably, less than 50 g/inch (20 g/cm), at room temperature. Thus, the ability to have peel strengths greater than 100 g/linear inch is a significant advantage because the resulting transparent conducting patterns have high durability which is advantageous in later processing steps.

The process of the invention comprises (b) contacting the substrate with a receiver, wherein the receiver comprises a base film, to provide an assemblage. The contacting may occur with the transparent conducting layer of the substrate; or with any optional layers that overlay the transparent conducting layer. By “contacted” is meant that the substrate is in close proximity, preferably within several microns of the receiver. The receiver may be off-set from the donor by, for example, previously printed layers, fibers or particles that act as spacers to provide a controlled gap between substrate and receiver. Vacuum and/or pressure can be used to hold the substrate and the receiver together. As one alternative, the substrate and receiver can be held together by fusion of layers at the periphery of the assembly. As another alternative, the substrate and receiver can be taped together and taped to the imaging apparatus. A pin/clamping system can also be used. As yet another alternative, the substrate can be laminated to the receiver. If the substrate and the receiver are flexible, the assembly can be conveniently mounted on a drum to facilitate the exposing or imaging step.

The receiver comprises a base film that may be any substrate described herein above for the substrate base film. Preferably the receiver is transparent in the visible and near-IR region and preferably the receiver has a dye that provides some absorption in the visible region. The dye in the receiver is referred to as an autofocus dye because it is used for focusing the laser IR light beams onto the assemblage. Various layers (e.g., an adhesive layer) may be coated onto the receiver base film to facilitate transfer of debris from the exposed substrate to the receiver. Other layers may be coated on the receiver base film to aid in the exposing and imaging of the assemblage.

The process of the invention comprises (c) exposing at least a portion of the assemblage to an IR light beam to provide an exposed donor having at least one exposed region, and at least one unexposed region having the transparent conducting pattern; wherein a ratio of the surface electrical resistivity of the exposed region and unexposed region is at least 103.

The exposing step is performed by application of an IR light beam to the assemblage. In many instances, exposing using light from, for example, a lamp or laser, is advantageous because of the accuracy and precision that can often be achieved. The IR light is preferably applied through the backside of the receiver. Laser radiation preferably is provided at a laser fluence of up to about 600 mJ/cm², and more preferably about 75-440 mJ/cm². Lasers with an operating wavelength of about 750 nm to about 1500 nm are preferred. Particularly advantageous are diode lasers, for example those emitting in the region of about 750 to about 870 nm and up to 1200 nm, which offer a substantial advantage in terms of their small size, low cost, stability, reliability, ruggedness and ease of modulation. Such lasers are available from, for example, Spectra Diode Laboratories (San Jose, Calif.). One device used for applying an image to the receiver is the Creo Spectrum Trendsetter 3244F, which utilizes lasers emitting near 830 nm. This device utilizes a Spatial Light Modulator to split and modulate the 5-25 Watt output from the ˜830 nm laser diode array. Associated optics focus this light onto the imageable elements. This produces 0.1 to 25 Watts of imaging light on the donor element, focused to an array of 50 to 240 individual beams, each with 10-200 mW of light in approximately 10×10 to 2×10 micron spots. Similar exposure can be obtained with individual lasers per spot, such as disclosed in U.S. Pat. No. 4,743,091. In this case each laser emits 50-300 mW of electrically modulated light at 780-870 nm. Other options include fiber-coupled lasers emitting 500-3000 mW and each individually modulated and focused on the media. Such a laser can be obtained from Opto Power in Tucson, Ariz.

Suitable lasers for the exposing include, for example, high power (>90 mW) single mode laser diodes, fiber-coupled laser diodes, and diode-pumped solid state lasers (e.g., Nd:YAG and Nd:YLF). Laser exposure dwell times can vary widely from, for example, a few hundredths of microseconds to tens of microseconds or more, and laser fluences can be in the range from, for example, about 0.01 to about 5 J/cm² or more.

The size and shape of the exposed region to provide a pattern (a pattern is defined as an arrangement of lines and shapes, e.g., a line, circle, square, or other shape) can be controlled by, for example, selecting the size of the IR light beam, the exposure pattern of the light beam, the duration of directed beam contact with the assemblage, and the materials of the donor. The assemblage is selectively exposed to IR light, preferably in the form of laser radiation, in an exposure pattern of a negative image of the desired pattern to be left on the donor. Sufficient radiation is applied to provide an exposed substrate having at least one exposed region, having at least partial removal of the transparent conducting layer; and at least one unexposed region having the transparent conducting pattern; wherein a ratio of the surface electrical resistance of the exposed region and unexposed region is at least 1000:1. Preferably the ratio of the surface electrical resistance of the exposed region and unexposed region is at least 100,000:1. The amount of radiation needed is typically determined empirically for each substrate using a matrix of scan speeds and laser power.

The applicants do not intend the invention to be bound by any mechanism of operation in the exposing process. However, in order to appreciate the advantages of the invention applicants offer the following insight. It appears, that to obtain a beneficial result, that only sufficient radiation is required to disrupt the uniformity of the transparent conducting layer in the exposed regions. Disruption of the uniformity of the transparent conducting layer results in disruption of the conductivity of the layer. Thus, only partial removal of the transparent conducting layer in the exposed regions may be required to obtain a beneficial result. A beneficial result may be obtained with, or without, the transfer of material in the exposed regions from the exposed donor to the exposed receiver.

Typically, to practice the process, the substrate is first mounted, with the transparent conducting layer facing outward, on a drum of a thermal transfer imaging apparatus; followed by contacting a receiver to the substrate to provide an assemblage. Sufficient exposing of the assemblage with an IR light beam provides at least partial disruption, and possibly removal, of the transparent conducting layer in the exposed regions. The unexposed regions, resulting from this negative imaging process, have the transparent conducting pattern undisturbed and remain part of the exposed donor.

One advantage of the negative imaging process is that the OD difference between the unexposed conducting region and the exposed nonconducting region is, typically and preferably, less than 0.1. The reason for this is that total transfer or removal of the transparent conducting layer is not required to obtain a useful conducting pattern. Thus, a preferred embodiment is the aforementioned process that provides an exposed substrate having at least one exposed region, and at least one unexposed region having the transparent conducting pattern; wherein the unexposed region has an average OD of less than 0.1 in the range of 400 nm to 700 nm; and the optical density difference between the unexposed region and exposed region is less than 0.1.

In a preferred embodiment the process further comprises (d) separating the exposed receiver from the exposed substrate to provide a patterned substrate having the transparent conducting pattern. In this embodiment the exposed donor preferably remains on the thermal transfer imaging drum and becomes the patterned substrate used in subsequent processing steps.

Another embodiment is a patterned substrate having a patterned conducting region and a nonconducting region made by the above disclosed process, wherein the patterned conducting region has an average OD of less than 0.1 in the range of 400 nm to 700 nm; and the optical density difference between the conducting region and nonconducting region is less than 0.1.

Another advantage of the negative imaging process becomes clear when multiple steps are needed to manufacture an article, for instance, a projected capacitance touchscreen. To produce such an article, a transparent conducting pattern in the form of a series of lines must be first provided. Subsequently it is necessary to print contact pads at the ends of each line to mediate electrical contact with external circuitry. Since the transparent conducting layers are typically less than 400 nm thick in order to maintain the required low OD in the range of 400 nm to 700 nm, it is difficult to make reliable electrical contacts directly to the thin transparent conducting patterns. A contact pad, printed to a thickness of about 1 micron, can serve as an effective electrical linker between the transparent conducting pattern and external circuitry, for instance, differential amplifiers. This printing of contact pads, must be accomplished in register with the transparent conducting pattern.

The transparent conducting pattern is provided on the exposed substrate while it is in a position on the thermal imaging drum. Separating the exposed receiver, provides a patterned substrate, that is the exposed substrate, which remains on the drum. The patterned substrate can now act as a receiver ready to receive a conducting transfer layer from a donor. Thus, in another embodiment a process further comprises:

(e) contacting the patterned substrate with a donor comprising: a base film and a conducting transfer layer; and

(f) transferring at least a portion of the conducting transfer layer onto the patterned substrate by thermal transfer to provide a second assemblage comprising a second patterned substrate having said transparent conducting pattern and a second conducting pattern; and a spent donor. In a preferred embodiment the second patterned substrate has the transparent conducting pattern contacting the second patterned conducting layer.

In another embodiment the process further comprises:

(g) separating the spent donor from the second patterned substrate.

The donor comprises a base film, as defined above, and a conducting transfer layer on the base film. The conducting transfer layer can be any conducting layer that can be transferable to a substrate in a thermal transfer process; for instance, using a imaging laser system. Examples include those transfer layers described in U.S. Pat. No. 6,114,088. Preferably the conducting transfer layer comprises conducting nanoparticles. Nanoparticles useful in forming the conducting transfer layer include conducting particles such as: carbon black, carbon nanotubes and metal-coated carbon nanotubes; metal particles such as: gold, silver, copper, iron, nickel, cobalt, platinum, palladium, chromium, molybdenum, tungsten, tantalum, tin, indium, lanthanum, gadolinium, ruthenium, titanium, yttrium, europium, gallium, zinc, magnesium, barium, cerium, strontium, lead, and antimony; doped and undoped metal oxide particles including transparent conductive oxides such as indium-tin-oxide (ITO), antimony-tin-oxide (ATO), tin oxide, fluorine-doped tin oxide, zinc oxide, aluminum-doped zinc oxide (AZO), and zinc tin oxide (ZTO); alloys thereof, composites thereof and core-shell structures thereof. Preferred conducting nanoparticles are selected from the group consisting of: gold, silver, copper, and alloys thereof; ITO, ATO, carbon black and carbon nanotubes. More preferred are silver nanoparticles with an average longest dimension of about 5 nm to about 1500 nm, and most preferred are silver nanoparticles with an average particle size of about 200 nm to about 400 nm.

A preferred conducting composition (A), useful in preparing the conducting transfer layer of the donor, comprises: (i) about 65 to about 95 wt %, based on the total weight of the conducting composition, of a conducting nanoparticle fraction selected from the group consisting of: carbon black; Ag, Cu and alloys thereof; and mixtures thereof; comprising a plurality of nanoparticles having an average longest dimension of about 5 nm to about 1500 nm; and (ii) about 5 to about 35 wt % of a dispersant comprising one or more resins selected from the group consisting of: conducting polymers selected from the group consisting of: polyaniline, polythiophene, polypyrrole, polyheteroaromatic vinylenes, and their derivatives; and nonconducting polymers selected from the group consisting of: acrylic and styrenic-acrylic latexes, and solution-based acrylics and styrenic-acrylic (co)polymers, and combinations thereof; copolymers of ethylene with one or more monomers selected from the group consisting of: (meth)acrylate(s), vinyl acetate, carbon monoxide and (meth)acrylic acid; polyvinylacetate and copolymers of vinylacetate. The term “carbon black: Ag, Cu, and alloys thereof; and mixtures thereof:” is meant to include mixtures of two or more species selected from the group consisting of: carbon black, Ag, Cu, alloys of Ag, and alloys of Cu

Preferably the conducting composition (A) comprises about 85 to about 90% of the conducting nanoparticle fraction with an average particle size of between 100 nm and about 400 nm. In a preferred embodiment the conducting nanoparticle is silver metal flake, with an average equivalent spherical diameter of about 100 to about 900 nm. In various aspects of the invention the conducting composition (A) comprises 96 wt % or greater, and preferably 98 wt % or greater, of components (i) and (ii) as stated above. In another aspect the conducting composition (A) consists essentially of the components (i) and (ii) as stated above.

The conducting composition (A), relative to conventional compositions, has high loadings of conducting nanoparticles. The composition is useful in preparing conducting transfer layers. The conducting composition (A) is unique in that it provides a conducting layer after thermal transfer, without the need for firing or burning-off of polymer binders.

Silver is a preferred conducting nanoparticle for the conducting composition (A). Preferred alloys include Ag—Pd, Ag—Pt and Ag—Cu. The metal powders are readily available from several commercial sources including: Ferro Corp., Electronic Materials Systems, South Plainfield, N.J.; Nanostructured & Amorphous Materials, Houston, Tex.; Inframat® Advanced Materials, Farmington, Conn.; Sumitomo Metal Mining Co., Ltd., Tokyo, Japan; and Mitsui Mining and Smelting Co., Ltd. Tokyo, Japan.

“Dispersant” refers to non-volatile organic or inorganic material that is used as a carrier or matrix medium for the conducting nanoparticle fraction. The dispersant includes one or more of the following components: polymers, oligomers, surface treatments, plasticizers, processing aids such as defoamers, surfactants, stabilizers, coating aids, pigments, dyes including near infrared dyes, and the like. The dispersant has several functions including: allowing the dispersion of the conducting nanoparticle fraction so it is evenly distributed; and contributing to the transfer properties, most notably the relative adhesion of the conducting transfer layer to the donor element and the thermal imaging receiver in the thermal transfer process. The dispersant also may contribute to the functional properties of the conducting transfer layer. For instance, the dispersant may be a conducting polymer.

The properties of the dispersant refer to the bulk properties of the fully formulated dispersant formulations, unless specifically noted. Preferred dispersants are polymers having a Tg of about −30° C. to about 90° C., and more preferably, about 30° C. to about 70° C.

Polymers useful as dispersants in the conducting compositions (A) include conducting organic polymers and doped versions of these polymers, e.g., polyaniline, polythiophene, polypyrrole, polyheteroaromatic vinylene, polyfuran, poly(para-phenylene), poly(phenylenevinylene), polyisothianaphthene, polyparaphenylene sulphide, and their derivatives. Preferred derivatives fall in one or more of the following categories: (a) stable conducting polymers such as polyaniline (PANI) and polyethylene dioxythiophene (PEDOT); (b) soluble or dispersible conducting polymers that form films using standard coating techniques, including PANI, PEDOT; and other alkyl- or alkoxy-substituted derivatives of conducting polymers such as poly(2,5 dialkoxy)paraphenylene vinylene and poly(3-hexyl)thiophene); and (c) conducting polymers that give high conductivity upon doping. Preferred conducting polymers are selected from the group consisting of: polyaniline; polythiophene; polypyrrole; polyheteroaromatic vinylenes; and their derivatives; preferably at a level of 1 to about 5 wt % based on the dry weight of the metal transfer layer composition.

Further polymers useful as dispersants are those selected from the group consisting of: acrylic and styrenic-acrylic latexes and solution-based acrylic and styrenic-acrylic (co)polymers including random and graft copolymers; and combinations thereof; copolymers of ethylene with one or more monomers selected from the group consisting of: (meth)acrylates, vinyl acetate, carbon monoxide and (meth)acrylic acid; polyvinylacetate and vinylacetate copolymers; and polyvinylpyrrolidone and its copolymers including polyvinylpyrrolidone-co-vinyl acetate. Preferably the solvent-soluble polymers within the group are characterized by a M_{w} of about 10,000 to about 200,000. A preferred dispersant comprises resins selected from the group consisting of: acrylic and styrenic-acrylic latexes, and solution-based acrylics and styrenic-acrylic (co)polymers, and combinations thereof.

Lower molecular weight oligomers and small molecules useful as processing aids in the dispersant include surfactants, for instance, those comprising siloxy-, fluoryl-, alkyl- and alkynyl-substituted surfactants. These include the BYK (Byk Chemie), ZONYL (DuPont), TRITON (Dow), SURFYNOL (Air Products) and DYNOL (Air Products) surfactants. Preferred are BYK 345, 346 and 348 and ZONYL FSO and FSN surfactants.

The conducting composition (A) is typically prepared by mixing the conducting nanoparticle fraction and the dispersant with a volatile carrier fluid to provide a fluid dispersion. Typically the volatile carrier fluid is water, an organic solvent, a gaseous material, or some combination thereof. The volatile carrier fluid is chosen to be compatible with the conducting nanoparticle fraction and any optional dispersant that is used. Examples of volatile carrier fluids include water, lower alcohols such as ethanol, aliphatic and aromatic hydrocarbons such as hexane, cyclohexane and xylenes; ethers such as dibutyl ether; ether alcohols such as 2-methoxyethanol; esters such as butyl acetate; and aliphatic and aromatic halocarbons such as 1,2-dichloroethane.

The donor, in various embodiments, comprises, in layered sequence, a base film, and optional LTHC layer, a conducting transfer layer and an optional protective strippable cover layer. The conducting transfer layer comprises the conducting composition (A) as described above. In one embodiment the conducting transfer layer consists essentially of the conducting composition (A) as described above. Other embodiments can include one or more additional layers interposed between the base film and the conducting transfer layer and/or on top of the conducting transfer layer. Thus, one or more other conventional thermal transfer donor element layers can be included in the second donor useful in the present invention, including but not limited to an interlayer, primer layer, release layer, ejection layer, thermal insulating layer, underlayer, adhesive layer, humectant layer, and light attenuating layer.

The donor can optionally have an LTHC layer disposed between the base film and the conducting transfer layer. LTHC layers for use in the donor include those described above; as well as metal radiation absorbers, either in the form of particles or as films deposited by various techniques such as thermal evaporation, e-beam heating and sputtering, as disclosed in U.S. Pat. No. 5,256,506, hereby incorporated by reference. Nickel and chromium are preferred metals for LTHC layers with chromium being especially preferred. Any other suitable metal for the heating layer can be used. The preferred thickness of the metal heating layer depends on the optical absorption of the metals used. For chromium, nickel/vanadium alloy or nickel, a layer of 80-100 Angstroms is preferred. Preferred radiation absorbers for LTHC layers utilized herein for the second donor are selected from the group consisting of: metal films selected from Cr and Ni; carbon black; graphite; and near infrared dyes with an absorption maxima in the range of about 600 to 1200 nm within the LTHC layer.

The donor comprising a conducting transfer layer can be prepared by applying the fluid dispersion of the conducting composition (A) onto the surface of the base film and volatizing the carrier fluid. Applying the fluid dispersion can be accomplished by any method that gives a uniform layer, or if desired, a patterned or nonuniform conducting transfer layer, as disclosed above. The carrier fluid is allowed to evaporate to provide the conducting transfer layer or the layer can be dried by any conventional method of drying including applying heat and/or vacuum.

Contacting the patterned substrate with a donor can be accomplished in an analogous manner as described above for contacting the substrate with a receiver.

Transferring at least a portion of the conducting transfer layer onto the patterned substrate by thermal transfer can be achieved by a laser-mediated transfer process in an analogous manner to the exposing step described above, with the exception, that sufficient radiation, preferably IR radiation in the 700 nm to 1200 nm region, is applied to achieve transfer of the conducting transfer layer from the donor to the patterned substrate, in the exposed regions. The transferring step can also use analogous methodologies to the conventional thermal transfer processes, such as heating in selected areas, as disclosed in US 2006/0088698 A1, paragraph [0100] through [0106].

The second assemblage provided by the transferring step comprises a second patterned substrate having the transparent conducting pattern and a second conducting pattern; and a spent donor. The spent donor can be separated from the second patterned substrate by peeling away the spent donor, or with any other method useful for separating.

The patterned substrates provided by the various embodiments of the invention can be used in many diverse electronic devices such as touchscreen sensors, organic light emitting diodes and photovoltaic current collectors, as well as others. In one embodiment the patterned substrate has a ratio of the surface electrical resistance of the exposed region and unexposed region is at least 103:1. In another embodiment the patterned substrate has at least two noncontiguous conducting regions separated by a gap having a gap width in the range of 5 microns to about 20 mm, and preferably in the range of 1 mm to about 20 mm. In another embodiment the patterned substrate has a conducting region having a conductivity of at least 10⁴ ohms per square. In another embodiment the patterned substrate has a peel force of greater than 100 grams per inch for removing the transparent conducting layer.

The substrate and transfer process of the invention are useful, for example, to reduce or eliminate wet processing steps of processes such as photolithographic patterning that is used to form many electronic and optical devices. In addition, laser exposing and thermal transfer can often provide better accuracy and quality control for very small devices, such as small optical and electronic devices, including, for example, transistors and other components of integrated circuits, as well as components for use in a display, such as electroluminescent lamps and control circuitry. Moreover, laser thermal transfer may, at least in some instances, provide for better registration when forming multiple devices over an area that is large compared to the device size.

### Materials and Methods

The following materials are used in the examples:

BAYTRON F E (H C Starck Corp, Newton, Mass.), a form of polyethylene dioxythiophene-poly(styrenesulfonate) dispersion (about 2.5 wt % solids);

BAYTRON P HC (H C Stark Corp), a form of polyethylene dioxythiophene-poly(styrenesulfonate) dispersion.

BYK-025 (Byk Chemie, Wesel, Germany) silicone defoamer;

JONCRYL 538 acrylic polymer emulsion (Johnson Polymer, Racine, Wis.);

MELINEX 535 polyester film (DuPont Teijin Film, Hopewell, Va.) is treated on both sides and promotes adhesion to aqueous coatings.

MELINEX 453 polyester film (DuPont Teijin Film, Hopewell, Va.) is treated on one side and promotes adhesion to most printing inks and industrial coatings.

OLIN 10 G nonionic surfactant (Olin Chemicals, city state);

SF 69 flake Ag, D50=0.82 micron, D90=1.83 microns (Ferro Corp, South Plainfield, N.J.);

SDA 4927 (H.W. Sands Co., Jupiter, Fla.), a near-IR dye;

SILQUEST A 187 coupling agent (Crompton Corporation) is 3-glycidoxy-propyltrimethoxysilane.

ZONYL FSA (E.I. DuPont De Nemours, Inc., Wilmington, Del.) anionic-fluoro surfactant.

### Receiver substrate

A receiver substrate used in the examples was a polyethylene terephthalate (PET) film containing Solvent Green 28 dye at about 0.40% by weight having an absorbance of 1.3 at 670 nm, and an absorbance of less than 0.08 at 830 nm.

### Organic LTHC Layer

An organic LTHC layer used in the examples was prepared as reported in Formulation L of the Examples of PCT/US05/38009: A LTHC coating formulation was prepared from the following materials: (i) demineralised water: 894 g; (ii) dimethylaminoethanol: 5 g; (iii) Hampford dye 822 (Hampford Research; formula corresponds to SDA 4927): 10 g; (iv) polyester binder (Amertech Polyester Clear; American Inks and Coatings Corp; Valley Forge; Pa.): 65 g of a 30% aqueous solution; (v) TEGO WET 251(4) (a polyether modified polysiloxane copolymer, Goldschmidt): 2.5 g; (vi) potassium dimethylaminoethanol ethyl phosphate: 14 g of an 11.5% aqueous solution [The 11.5% aqueous solution was prepared by combining three parts water and 0.5 parts ethyl acid phosphate (Stauffer Chemical Company, Westport, Conn.: Lubrizol, Wickliffe, Ohio) and sufficient 45% aqueous potassium hydroxide to achieve a pH of 4.5, followed by addition of sufficient dimethylaminoethanol to achieve a pH of 7.5 and finally dilution with water to achieve five parts total of final aqueous solution of 11.5 relative mass percent of water-free compound.]; (vii) crosslinker CYMEL 350 (a highly methylated, monomeric melamine formaldehyde resin, Cytec Industries Inc. West Paterson, N.J.): 10 g of a 20% solution; and (viii) ammonium p-toluene sulphonic acid: 2 g of a 10% aqueous solution.

Ingredients (ii) and (iii) were added to the water and allowed to stir for up to 24 hours before addition of the other ingredients in the order shown. There was no need to filter this formulation. The formulation was applied in an in-line coating technique as follows: A PET base film composition was melt-extruded, cast onto a cooled rotating drum and stretched in the direction of extrusion to approximately 3 times its original dimensions at a temperature of 75° C. The cooled stretched film was then coated on one side with the LTHC coating composition to give a wet coating thickness of approximately 20 to 30 μm. A direct gravure coating system was used to apply the coatings to the film web. A 60QCH gravure roll (supplied by Pamarco) rotated through the solution, taking solution onto the gravure roll surface. The gravure roll rotated in the opposite direction to the film web and applied the coating to the web at one point of contact. The coated film was passed into a stenter oven at a temperature of 100-110° C. where the film was dried and stretched in the sideways direction to approximately 3 times its original dimensions. The biaxially stretched coated film was heat-set at a temperature of about 190° C. by conventional means. The coated polyester film is then wound onto a roll. The total thickness of the final film was 50 μm; the dry thickness of the transfer-assist coating layer is of 0.07 μm. The PET base film contained either Disperse Blue 60 or Solvent Green 28 dye to give a final dye concentration of typically 0.2% to 0.5% by weight in the polymer of the base film. The base film containing the Disperse Blue 60 dye (0.26% by weight) had an absorbance of 0.6±0.1 at 670 nm, and an absorbance of <0.08 at 830 nm. The base film containing the Solvent Green 28 dye (0.40% by weight) had an absorbance of 1.2 at 670 nm, and an absorbance of <0.08 at 830 nm. These base films are herein referred to as: Organic LTHC Blue PET base film and Organic LTHC Green PET base film.

### Optical Characterization

Visual light transmission was measured in the range 400 nm to 700 nm using a Shimadzu UV-1700 UV-V is spectrophotometer (Shimadzu Scientific Instruments, Inc., Colombia, Md.). When the optical density difference between exposed and unexposed regions of the substrate is reported herein, the exposed region was placed in the sample beam path and the unexposed region was placed in the reference beam path. The relative optical density was then measured from 400 to 700 nm.

### Electrical Characterization

The surface electrical resistance (SER) of the substrate was measured by applying two dots of conducting, silver adhesive to the transparent conducting layer, spaced one inch apart, allowing it to dry, and then contacting these dots with the probes of a Fluke multimeter (Fluke Corporation, Everett, Wash.). The resistance is read directly from the meter. For the examples presented herein the SER is equated with the sheet resistance for unpatterned substrates.

### Peel Force Characterization

The peel force for separation of the transparent conducting layer from the base film was measured with an IMASS SP-2000 peel tester (IMASS Inc., Accord, Mass.). An adhesive was applied to a glass plate, and a 1″ wide strip of the donor, with the conducting layer facing the adhesive, was adhered to the adhesive. The donor was peeled from the substrate at a 180° angle.

### Thermal Imaging Equipment

A Creo Trendsetter® 3244 was utilized. The Creo Trendsetter® 3244 (Kodak Graphic Communications Group, Rochester, N.Y. USA) is a standard drum-type imager which utilizes a Thermal 1.7 Head with a 20 watt maximum average operating power at a wavelength of 830 nm with 2400 dpi resolution. The 3244 Trendsetter® was operated under ambient conditions. Films were mounted using vacuum hold down to a standard plastic or metal carrier plate clamped mechanically to the drum. Contact between the donor and receiver was established by ˜600 mm of Hg vacuum pressure. Control of the laser output was under computer control to build up the desired image pattern. Laser power and drum speed were controllable and were often adjusted in an iterative fashion to optimize pattern quality as judged by visual inspection.

### Transparent Conducting Polymer Coating Formulation

A transparent conducting polymer coating formulation comprising polyethylene dioxythiophene was first prepared using the materials listed in Table 1. Methanol (1.5 mL portion) was added to the SDA 4927 dye and stirred for 5 minutes. The resulting solution was decanted from the undissolved dye and subsequently added to a rapidly stirred (about 700 rpm) dispersion of the Baytron F E. This process was repeated with further portions of methanol (5 portions), with the last portion taking up and transferring any remaining undissolved dye. The resulting mixture was stirred for 1.5 h, and transferred to bottle and roll mixed for 55 h followed by vacuum filtering through WHATMAN #40 filter paper.

TABLE 1
Transparent Conducting Polymer Coating Composition

| Material | Weight (g) |
|---|---|
| BAYTRON F E | 78.63 |
| SDA 4927 | 0.127 |
| methanol | 7.25 |

### EXAMPLE 1

This example illustrates the formation of a substrate of the invention. The coating composition of Table 1 was coated using a Bushman CN4 coating rod (Bushman Corp., Cleveland Ohio) with a WATERPROOF CV coating system (E.I. DuPont De Nemours, Inc., Wilmington, Del.) onto MELINEX 535 (DuPont-Teijin Films, Hopewell, Va.). The coated base film was dried for 10 min at 45° C. The measured OD at 830 nm was 0.24. The OD throughout the visible range, 400-700 nm, was less than 0.1 at all wavelengths. The thickness of the transparent conducting layer was measured with a Tencor P-15 stylus profilometer (KLA-Tencor, San Jose, Calif.) to be 150 nm. The surface resistance of the conducting layer, was 650 Ohms.

The peel force for separation of the transparent conducting layer from the base film was measured with an Imass SP-2000 peel tester. The measured peel force was 4300 g per linear inch (1700 g/linear cm) and the failure occurred at the adhesive/glass interface. This demonstrated that the adhesion of the transparent conducting layer to the base film was stronger than the adhesion between the adhesive and the glass.

### EXAMPLE 2

This example illustrates the method for making a transparent conducting pattern.

The substrate of Example 1 was exposed with near-IR laser light using a CREO Trendsetter exposure unit as described in the methods. The substrate from Example 1 was dried for 60 min at 50° C. The substrate was mounted onto the drum of the exposure unit with the transparent conducting layer facing out from the core of the drum. A receiver consisting of a PET film (2 mil, 0.05 mm) containing Solvent Green 28 dye, as disclosed in the materials section, was loaded second. Films were mounted using vacuum hold down to a standard plastic or metal carrier plate clamped mechanically to the drum. The assemblage was exposed in selected regions at 18 W at 830 nm at a drum speed of 60 rpm from the side through the receiver.

The pattern that was exposed to the imaging laser consisted of a contiguous exposed region such that the unexposed regions comprised a set of about 50 lines that were 1 mm wide by about 25 cm long. The unexposed regions maintained their electrical conductivity. The two-probe resistance of such a line was typically 75 Kohms. Given that the length to width ratio of this line was 25 cm divided by 1 mm, equal to 250, the corresponding sheet resistance equaled 75,000/250, or 300 Ohms per square. The regions that were exposed to the imaging laser lost their conductivity and became insulating. The two-probe resistance in the exposed regions was infinite. Thus the ratio of the surface electrical resistivity of the exposed and unexposed region was much greater than 100,000:1. The optical density difference between the exposed and unexposed regions was less that 0.1 throughout the wavelength range 400-700 nm.

### EXAMPLE 3

This example illustrates the method for making a patterned substrate having a transparent conducting pattern and a second conducting pattern.

A metal composition comprising Ag flake was first prepared using the materials listed in Table 2. The composition was mixed in a vial with an ultrasound probe (Dukane Co., Model 40TP2000, Transducer Model 41C28) for 15 min, during which the mixture was stirred with a spatula at 5 min intervals. The vial was placed in a water bath with sonication for 1 h, during which the mixture was stirred with a spatula at 0.5 h intervals. The mixture was then treated in a water bath at RT with probe sonication for an additional 15 min, during which the mixture was stirred with a spatula at 5 min intervals. The resulting dispersion was filtered twice through an 8 micron stainless steel screen (Twill Dutch Weave 325×2300, Sefar America Inc.).

TABLE 2
Metal Composition for Metal Transfer Layer

| Material | Weight (g) |
|---|---|
| SF 69 flake Ag | 24.015 |
| DI water | 12.7 |
| JONCRYL 538 acrylic | 13.338 |
| ZONYL FSA surfactant | 0.476 |
| BYK-025 dispersant | 0.743 |

The metal composition (8 mL) was coated onto an Organic LTHC Green PET base film using the WATERPROOF CV coating system at 5.8 ft/min (1.76 m/min) with #5 CN formed rod and dried at 45° C. for 20 min, to provide a donor having a base film and a metal transfer layer of thickness of about 3.4 micron.

A patterned substrate comprising the transparent conducting pattern as described in example 2 was prepared. After the exposing step was complete, the receiver was removed from the drum, while the patterned substrate having the transparent conducting pattern remained on the drum. The aforementioned donor, having a base film and a metal transfer layer, was loaded onto the drum and exposed in a pattern at 13.6 W and 60 rpm. The metal transfer layer transferred from the donor to the patterned substrate in the exposed regions. This exposing step printed contact pads of about 1 mm×3 mm onto the ends of the lines making up the transparent conducting pattern. The spent donor was removed from the drum to provide the second patterned substrate having transparent conducting lines and contact pads comprising silver, which could function as the x- or y-direction of a digitizer array for touchscreens.

### EXAMPLE 4

This example illustrates the lamination of a digitizer array. The processes of Examples 2 and 3 were performed twice to produce two patterned substrates having the x- and y-direction digitizer arrays. The patterned substrates, with the x- and y-directioned conducting patterns facing each other, were laminated by applying a layer of NOA-71 UV-adhesive (Norland Optical Adhesives, Cranbury N.J.) to one surface having the transparent conducting pattern, laying the second patterned substrate on the adhesive layer and applying pressure to the substrates to provide a substantially uniform laminate with an adhesive layer thickness of about 50 microns. The laminate was exposed to UV light (Spectroline SB-1 OOP, Norland Optical Adhesives) to cure the NOA-71 UV adhesive layer. The result was a digitizer array with exposed contact pads suitable for integration with touchscreen circuitry.

### COMPARATIVE EXAMPLES A AND B

The following examples illustrate that a donor film comprising a base film and a transparent conducting layer wherein the donor film has an OD of less than 0.1 to 0.6 at about 830 nm, does not have sufficient absorption in the wavelength region corresponding to the IR light beam, of the imaging laser, to facilitate patterning of the transparent conducting layer. The donor film composition was made in accordance with US 2006/0088698 A1, Majumdar, et al, coating composition A listed in paragraph [0156]. The donor film did not have any near-IR dye present.

The donor film composition listed in Table 3 was prepared by adding a mixture of N-methylpyrrolidone (NMP), isopropanol, diethylene glycol, OLIN 10G, and SILQUEST A 187 coupling agent; to a stirring pot of BAYTRON P HC. The mixture was sealed in a bottle and roll mixed for 55 h, and vacuum filtered through WHATMAN 40, ashless, 8 micron filter paper. The filtered material was bottled and sealed and rolled 4 days prior to use.

TABLE 3
Comparative Example A-D formulation

| Trade Name | Description | Weight (g) |
|---|---|---|
| BAYTRON P HC | polyethylene dioxythiophene- | 44.398 |
| | poly(styrenesulfonate) | |
| OLIN 10G (10 | nonionic surfactant | 0.25 |
| wt % aqueous) | | |
| NMP | solvent | 2.58 |
| diethylene glycol | solvent | 2.01 |
| SILQUEST A | 3-glycidoxy- | 0.91 |
| 187 | propyltrimethoxysilane | |
| isopropanol | solvent | 2.16 |
| Total | | 52.312 |

Comparative example A and B substrates were prepared using the coating conditions listed in Table 4A and the general coating methods of Example 1 to provide transparent conducting layers of an average thickness of 178 and 140 nm, respectively.

TABLE 4A
Coating Conditions for Comparative Examples A and B

| | | | Bead | Drying | Thickness |
|---|---|---|---|---|---|
| Comparative | | | vol | conditions | average |
| Example | Base film | Rod | (mL) | (° C.)/(min) | (nm) |
| A | MELINEX | CN 04 | 6.0 | 45/10 | 178 |
| | 535 | | | | |
| B | MELINEX | CN 04 | 6.0 | 45/10 | 140 |
| | 453 | | | | |

TABLE 4B
Optical and Electrical Properties of Comparative Examples A and B

| | | | | Average | |
|---|---|---|---|---|---|
| | | | Average | OD | |
| | | | % T from | between | |
| Comparative | OD at 830 | R_{q}^{a} | 400-700 | 400-700 | SER |
| Example | nm | (nm) | nm | nm | (Ω) |
| A | 0.033 | 9 | 89% | 0.13 | 576 |
| B | 0.026 | 13 | 89% | 0.13 | 665 |

^{a}average surface roughness

The substrates of comparative example A and B were dried for 60 min at 50° C. and each donor mounted in a Creo Trendsetter on the drum first with the transparent conducting layer facing out from the core of the drum. A cover sheet consisting of a 2 mil (0.05 mm) PET film containing Solvent Green 28 dye (0.40% by weight) having an absorbance of 1.2 at 670 nm, (used to absorb the signal from the autofocus laser) was loaded second. This assemblage was imaged at a matrix of exposures. Three drum speeds tested were 40 rpm, 60 rpm, and 80 rpm. At each drum speed, the power was varied from 12 W to 20 W in 1 W increments. After exposing, the cover sheet was removed from the Trendsetter to provide the results of the exposing step. Comparative example A and B failed to give any conducting pattern, or any visible evidence of having been exposed to the IR light beam, as a result of the exposing step under any of the exposure conditions in the matrix tested. This indicates that thin conducting layers of polyethylene dioxythiophene-poly(styrenesulfonate) dispersion were not sufficiently absorptive in the 830 nm range to provide patterning of the thin films.

### COMPARATIVE EXAMPLES C AND D

The following examples illustrate that a substrate comprising a base film and a transparent conducting layer of polyethylene dioxythiophene-poly(styrenesulfonate) in the range of 400 nm or higher, has sufficient OD in the 830 nm range to allow patterning with a near-IR laser, but the transparent conducting layers have an OD much higher than 0.10 in the 400-700 nm range.

TABLE 5A
Coating Conditions for Comparative Examples C and D

| | | | Bead | Drying | Thickness |
|---|---|---|---|---|---|
| Comparative | | | vol | conditions | average |
| Example | Base film | Rod | (mL) | (° C.)/(min) | (nm) |
| C | MELINEX | CN 10 | 10.0 | 45/10 | 375 |
| | 535 | | | | |
| D | MELINEX | CN 10 | 10.0 | 45/10 | 440 |
| | 453 | | | | |

TABLE 5B
Optical and Electrical properties of Comparative Examples C and D

| | | | Average | Average | |
|---|---|---|---|---|---|
| | | | % T | OD | |
| | | | between | between | |
| Comparative | OD at 830 | R_{q} | 400-700 | 400-700 | SER |
| Example | nm | (nm) | nm | nm | (Ω) |
| C | 0.113 | 15 | 83% | 0.15 | 234 |
| D | 0.096 | 12 | 83% | 0.15 | 251 |

The substrates of comparative example C and D were dried for 60 min at 50° C. and each donor mounted in a Creo Trendsetter on the drum first with the transparent conducting layer facing out from the core of the drum. A cover sheet consisting of a 2 mil (0.05 mm) PET film containing Solvent Green 28 dye (0.40% by weight) having an absorbance of 1.2 at 670 nm, (used to absorb the signal from the autofocus laser) was loaded second. This assemblage was imaged at a matrix of exposures. Three drum speeds tested were 40 rpm, 60 rpm, and 80 rpm. At each drum speed, the power was varied from 12 W to 20 W in 1 W increments. After exposing, the cover sheet was removed from the Trendsetter to provide the results of the exposing step. Comparative example C and D, under some of the exposure conditions, did provide conductive patterns on the exposed substrates in the unexposed regions while the exposed regions had no measurable conductivity. However for example C the OD of the conductive pattern was 0.15 and the OD difference between the exposed regions and unexposed regions ranged from 0.17 to 0.23 in the 400 nm to 700 nm range. For example D the OD of the conductive pattern was 0.15 and the OD difference between the exposed regions and unexposed regions ranged from −0.03 to +0.06 in the 400 nm to 700 nm range. This indicates that thick conducting layers of polyethylene dioxythiophene-poly(styrenesulfonate) dispersion, in the range of 400 nm and higher, are sufficiently absorptive in the 830 nm range to provide patterning of the conductive layers upon exposure to 830 nm radiation. However, the OD of the films at these thicknesses is much higher than the desired OD of 0.1 or less. Furthermore, in some cases the OD difference between the exposed and unexposed regions in the 400 to 700 nm range is much higher than the desired OD difference of 0.1 or less.

1. A process for making a transparent conducting pattern comprising:
(a) providing a substrate comprising: a base film and a transparent conducting layer disposed on the base film wherein the substrate has an OD of about 0.1 to 0.6 at 830 nm, and the transparent conducting layer has an average OD of less than 0.1 in the range of 400 to 700 nm;
(b) contacting the substrate with a receiver, wherein the receiver comprises a base film, to provide an assemblage;
(c) exposing a portion of the assemblage to an IR light beam to provide an exposed substrate having at least one exposed region, and at least one unexposed region having the transparent conducting pattern; and an exposed receiver; wherein a ratio of the surface electrical resistance of the exposed region and unexposed region is at least 1000:1.

2. The process of claim 1, further comprising:
(d) separating the exposed receiver from the exposed substrate to provide a patterned substrate having the transparent conducting pattern.

3. The process of claim 1, wherein the transparent conducting layer is an organic conductor.

4. The process of claim 1, wherein the substrate has an OD of about 0.1 to 0.3 at 830 nm.

5. The process of claim 1, wherein the transparent conducting layer comprises polyethylene dioxythiophene.

6. The process of claim 1, wherein the transparent conducting layer has a thickness of less than 400 nm.

7. The process of claim 1, wherein the substrate further comprises one or more near-IR dye(s) having an absorption maximum in the range of about 600 to about 1200 nm within the donor.

8. The process of claim 7, wherein the one or more near-IR dye(s) is disposed in the transparent conducting layer.

9. The process of claim 7, wherein the substrate further comprises an LTHC layer interposed between the base film and the transparent conducting layer and said LTHC layer comprises one or more dielectric polymers and the one or more near-IR dye(s).

10. The process of claim 1, wherein the transparent conducting layer has a peel force of greater than 100 grams per inch for removing the transparent conducting layer.

11. The process of claim 1, wherein, within the exposed substrate, the unexposed region has an average OD of less than 0.1 in the range of 400 nm to 700 nm and the optical density difference between the unexposed region and exposed region is less than 0.1.

12. The process of claim 2, further comprising:
(e) contacting the patterned substrate with a donor comprising: a base film and a conducting transfer layer;
(f) transferring at least a portion of the conducting transfer layer onto the patterned substrate by thermal transfer to provide a second assemblage comprising a second patterned substrate having said transparent conducting pattern and a second conducting pattern and a spent donor.

13. The process of claim 12, further comprising:
(g) separating the spent donor from the second patterned substrate.

14. The process of claim 12, wherein the conductive transfer layer comprises conducting nanoparticles selected from the group consisting of: gold, silver, copper, and alloys thereof; ITO, ATO, carbon black and carbon nanotubes.

15. The process of claim 12, wherein the conductive transfer layer comprises a conducting composition (A), comprising:
(i) about 65 to about 95 wt %, based on the total weight of the conducting composition, of a conducting nanoparticle fraction selected from the group consisting of: carbon black; Ag, Cu and alloys thereof; and mixtures thereof; comprising a plurality of nanoparticles having an average longest dimension of about 5 nm to about 1500 nm; and
(ii) about 5 to about 35 wt % of a dispersant comprising one or more resins selected from the group consisting of: conducting polymers selected from the group consisting of polyaniline, polythiophene, polypyrrole, polyheteroaromatic vinylenes, and their derivatives; nonconducting polymers selected from the group consisting of acrylic and styrenic-acrylic latexes, and solution-based acrylics and styrenic-acrylic (co)polymers, and combinations thereof; copolymers of ethylene with one or more monomers selected from the group consisting of (meth)acrylate(s), vinyl acetate, carbon monoxide and (meth)acrylic acid; and polyvinylacetate and copolymers of vinylacetate.

16. An electronic device made by the process of claim 1.

17. An electronic device made by the process of claim 12.

18. The electronic device of claim 16, wherein within the exposed substrate, the transparent conducting pattern has an average OD of less than 0.1 in the range of 400 nm to 700 nm; and the optical density difference between the unexposed region and exposed region is less than 0.1.

19. The electronic device of claim 16, wherein within the exposed substrate, the transparent conducting pattern has a sheet resistance of less than 10⁴ Ohms per square.

20. The electronic device of claim 16, that is selected from the group consisting of touchscreen sensor, organic light emitting diode, and photovoltaic current collector.

21. The electronic device of claim 17, wherein within the patterned substrate, the transparent conducting pattern has an average OD of less than 0.1 in the range of 400 nm to 700 nm; and the optical density difference between the unexposed region and exposed region is less than 0.1.

22. The electronic device of claim 17, wherein within the patterned substrate, the transparent conducting pattern has a sheet resistance of less than 10,000 Ohms per square.

23. A substrate comprising a base film and a transparent conducting layer disposed on the base film, wherein the substrate has an OD of about 0.1 to 0.6 at 830 nm, and the transparent conducting layer comprises polyethylene dioxythiophene and has an OD of less than 0.1 in the range of 400 to 700 nm.

24. The substrate of claim 23, wherein the transparent conducting layer has a peel force of greater than 100 grams per inch for removing the transparent conducting layer.

25. The substrate of claim 23, wherein the transparent conducting layer has a thickness of 400 nm or less.

26. The substrate of claim 23, further comprising one or more near-IR dye(s) having an absorption maximum in the range of about 600 to about 1200 nm within the donor.

27. The substrate of claim 26, wherein the one or more near-IR dye(s) is disposed in the transparent conducting layer.

28. The substrate of claim 26, further comprising an LTHC layer interposed between the base film and the transparent conducting layer and said LTHC layer comprises one or more dielectric polymers(s) and one or more near-IR dye(s).

29. The substrate of claim 26, wherein the one or more near-IR dye(s) is a cyanine compound(s) selected from the group consisting of: indocyanines, phthalocyanines including polysubstituted phthalocyanines and metal-containing phthalocyanines, and merocyanines.
